(19) United States
(12) Patent Application Publication
(10) Pub. No.: US 2015/0048499 A1
(43) Pub. Date: Feb. 19, 2015

(54) FINE-PITCH PILLAR BUMP LAYOUT STRUCTURE ON CHIP

(71) Applicants: Macrotech Technology Inc., Hsinchu (TW); Powertech Technology Inc., Hsinchu (TW)

(72) Inventors: Kuo-Jui TAI, Hsinchu (TW); Li-Jen LIN, Hsinchu (TW); Shou-Chian HSU, Hsinchu (TW)

(73) Assignees: MACROTECH TECHNOLOGY INC., Hsinchu (TW); POWERTECH TECHNOLOGY INC., Hsinchu (TW)

(21) Appl. No.: 13/969,240

(22) Filed: Aug. 16, 2013

(51) Int. Cl. H01L 23/498

(52) U.S. Cl. CPC H01L 23/49811
USPC 257/737

(57) ABSTRACT

Disclosed is a fine-pitch pillar bump layout structure on chip, comprising a chip, a passivation layer and at least two pillar bumps. Bonding pads of the chip are disposed along an X-axis. Openings of the passivation layer have a first aspect ratio. Pillar bumps are disposed on the bonding pads and each has a pillar body and a solder cap. Each pillar body has a plurality of symmetrical raised blocks disposed on the passivation layer and extended in both directions of Y-axis. The pillar bodies have shrunk bump widths along the X-axis so that a second aspect ratio is at least 1.5 times greater than the first aspect ratio and to partially expose the bonding pads and to make the central points of the pillar bodies be vertically aligned with the central points of the openings of the passivation layer.

### FIELD OF THE INVENTION

The present invention relates to a layout structure of a bumped semiconductor device, more specifically to a fine-pitch pillar bump layout structure on chip.

### BACKGROUND OF THE INVENTION

Most of the semiconductor devices such as DRAM has migrated from wire bonding interconnection to flip chip interconnection toward Wafer Level Chip Scale Packages (WLCSP). However, as the continuous die shrinkage with bonding pad miniaturization, fabrication of pillar bumps with solder caps such as Cu pillar bump (CPB) on fine-pitch bonding pad layout becomes more difficult where the bonding pad pitch is less than 80 μm. When flip-chip bonding a bumped chip, solder caps will easily bridge with the adjacent pillar bumps leading to electrical short. Moreover, encapsulation the gaps between bumped chips and substrates with underfill material after flip-chip bonding becomes more difficult. The conventional solution is to fabricate smaller pillar bumps, however, solder joints become smaller which are easily broken due to external stresses.

An alternative solution is to make pillar bumps longer but narrower become finger-like bumps extended to one side as revealed in Taiwan Patent Published No. 200837912 entitled “IC Chip Having Finger-Like Bumps”, however, the above mentioned bump structure is implemented in Inner Lead Bonding (ILB) for Au bumps in COF (Chip-On-Film) packages without solder bleeding issues. Moreover, one end of finger-like Au bump is extended to one direction which will induce unbalanced stress on Al pads, i.e., Au bump dimension is greater than the passivation opening, which is quite different from the issue encountered by pillar bumps with solder caps in a fine-pitch pillar bump layout.

### SUMMARY OF THE INVENTION

The main purpose of the present invention is to provide a fine-pitch pillar bump layout structure on chip to avoid bridging of adjacent solder caps of fine-pitch pillar bumps and to have sufficient solder jointing area of pillar bumps with fine-pitch pillar bump layout and to align to the passivation opening on top of bonding pads to achieve the best combination of balanced solder joint stresses.

The second purpose of the present invention is to provide a fine-pitch pillar bump layout structure on chip to improve non-coplanarity issue of pillar bumps with different functions disposed on bonding pads as well as on a composite passivation.

According to the present invention, a fine-pitch pillar bump layout structure on chip is revealed, comprising a chip, a passivation layer, a first pillar bump, and a second pillar bump. A first bonding pad and a second bonding pad are disposed on the active surface of the chip arranged along the X-axis. The passivation layer is formed on the active surface of the chip and has a first opening and a second opening with the first aspect ratio where the distance between the central point of the first bonding pad and the central point of the second bonding pad is defined on the X-axis and is not greater than 80 μm. There is a first Y-axis and a second Y-axis parallel to each other and perpendicular to the X-axis where the central point of the first opening is located on the first Y-axis, and the central point of the second opening is located on the second Y-axis. The first pillar bump is disposed on the first bonding pad and includes a first pillar body and a first solder cap. The second pillar bump is disposed on the second bonding pad and includes a second pillar body and a second solder cap. The first pillar body has a pair of first symmetrical raised blocks extended toward both directions along the first Y-axis and the second pillar body has a plurality of symmetrical raised blocks extended toward both directions along the second Y-axis where the first symmetrical raised blocks and the second symmetrical raised blocks are disposed on the passivation layer and the first pillar body and the second pillar body individually have shrunk bump widths along the X-axis so that the first pillar body and the second pillar body have a second aspect ratio which is 1.5 times greater than the first aspect ratio to partially expose the first bonding pad and the second bonding pad and to make the first pillar body vertically aligned to the central point of the first opening along the first Y-axis and the second pillar body is vertically aligned to the central point of the second opening.

### DESCRIPTION OF THE DRAWINGS

FIG. 1 is a partial three-dimensional view of a fine-pitch pillar bump layout structure on chip according to the preferred embodiment of the present invention.

FIG. 2 is a cross-sectional view of the fine-pitch pillar bump layout structure along the cross-sectional line 2-2 in FIG. 1 according to the preferred embodiment of the present invention.

FIG. 3 is a cross-sectional view of the fine-pitch pillar bump layout structure along the cross-sectional line 3-3 in FIG. 1 according to the preferred embodiment of the present invention.

FIG. 4 is a top view of the fine-pitch pillar bump layout structure according to the preferred embodiment of the present invention.

FIG. 5 is a cross-sectional view of another fine-pitch pillar bump layout structure on chip according to the various embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

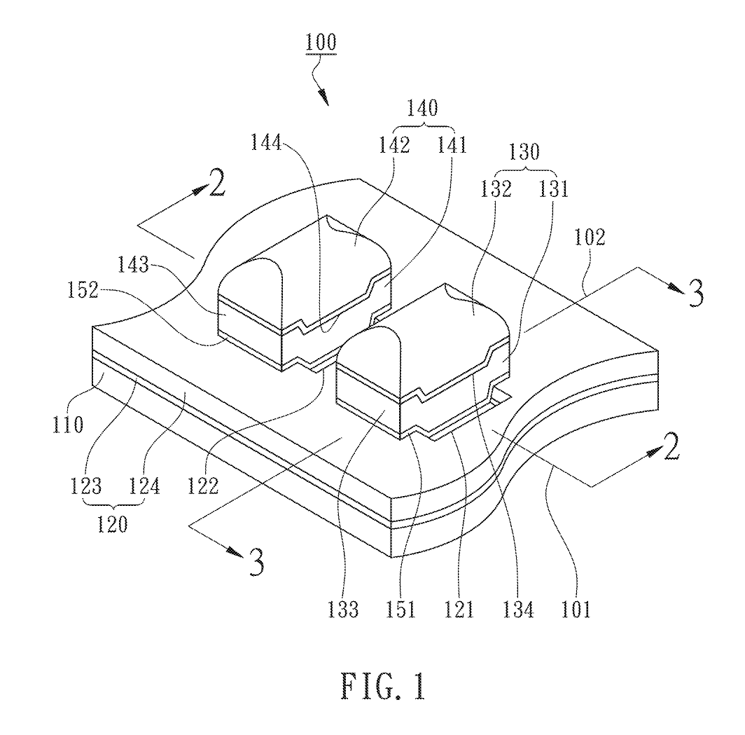

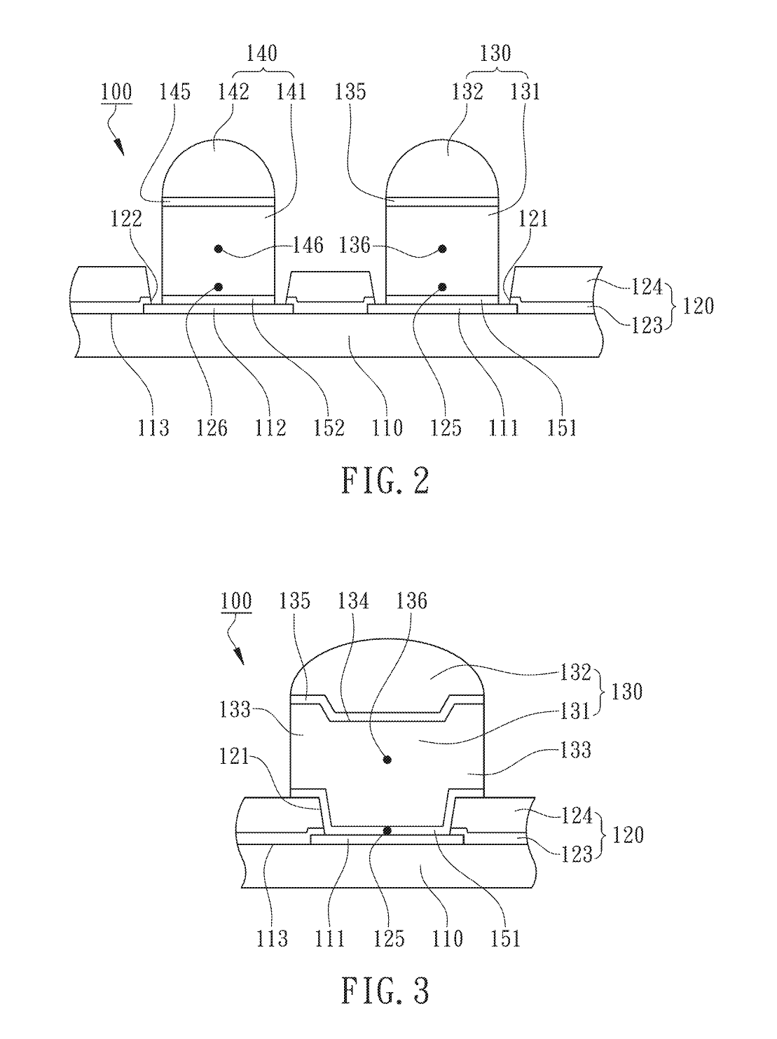

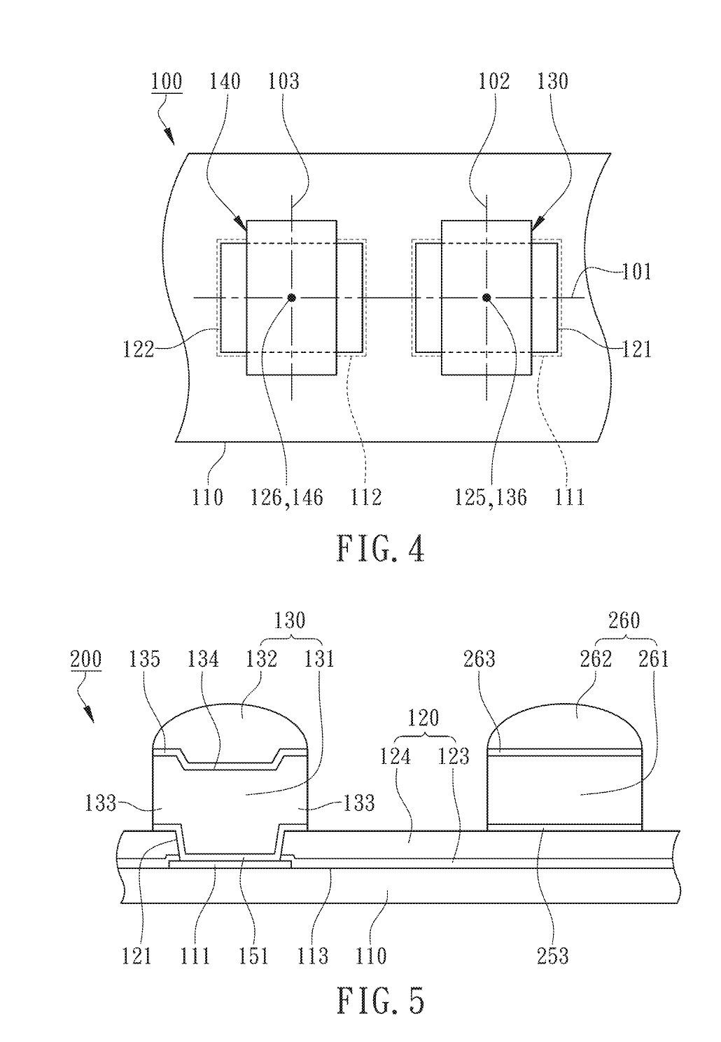

According to the preferred embodiment of the present invention, a fine-pitch pillar bump layout structure on chip is revealed and illustrated in FIG. 1 for a partial three-dimensional view, FIG. 2 for a cross-sectional view along the cross-sectional line 2-2 in FIG. 1, FIG. 3 a cross-sectional view along the cross-sectional line 3-3 in FIG. 1, and FIG. 4 for a top view. The fine-pitch pillar bump layout structure 100 includes a chip 110, a passivation layer 120, a first pillar bump 130, and a second pillar bump 140.

The chip 110 is a semiconductor chip having IC devices, which can be a memory device such as DRAM, fabricated on an active surface 113 of the chip 110. A first bonding pad 111 and a second bonding pad 112 are disposed on the active surface 113 of the chip 110 and disposed along the X-axis 101 as I/O terminals for IC.

The passivation layer 120 is disposed on the active surface 113 of the chip 110 as the IC protection on the active surface 113. The passivation layer 120 has a first opening 121 and a second opening 122 each having a first aspect ratio, wherein the length and the width of the opening is the same when the aspect ratio is 1. The lengths and the widths of the first opening 121 and the second opening 122 range from 30 μm to 80 μm and 42 μm to be more specific. The distance between the central point 125 of the first opening 121 to the central point 126 of the second opening 122 is defined on the X-axis 101 and is less than 80 μm, i.e., the opening pitch between the first opening 121 and the second opening 122 on the X-axis 101 is not greater than 80 μm where both ends of the distance are connecting to a first Y-axis 102 and a second Y-axis 103 parallel to each other and perpendicular to the X-axis 101. Moreover, the central point 125 of the first opening 121 is located on the first Y-axis 102 and the central point 126 of the second opening is located on the second Y-axis 103 as shown in FIG. 4. Preferably, the passivation layer 120 includes a primary passivation 123 and an additional organic passivation 124 to form a composite passivation with a total thickness over 5 μm to increase the isolation and protection of the active surface 113 of the chip 110 and to enhance stress buffering effect of pillar bumps. The material of the additional organic passivation 124 can be PI (Polyimide) or PBO (Polybenzoxazole) with a thickness much greater than the thickness of primary passivation 123.

The first pillar bump 130 is disposed on the first bonding pad 111 and includes a first pillar body 131 and a first solder cap 132. The second pillar bump 140 is disposed on the second bonding pad 112 and includes a second pillar body 131 and a second solder cap 142. The material of the first pillar body 131 and the second pillar body 141 is metal which can not be melted during solder reflowing such as Cu. The shapes of the first pillar body 131 and the second pillar body 141 disposed on the active surface 113 are not circular such as rectangular strips. The first solder cap 132 and the second solder cap 142 are lead-free solder such as Sn—Ag or Sn—Ag—Cu. Furthermore, in a more specific structure, a first barrier layer 135 is disposed between the first pillar body 131 and the first solder cap 132 and a second barrier layer 145 is disposed between the second pillar body 141 and the second solder cap 142 to provide extra adhesion between the solder caps 132 and 142 and the corresponding pillar bodies 131 and 141 and to avoid solder migration toward the first pillar body 131 and the second pillar body 141. The material of the first barrier layer 135 and the second barrier layer 145 can be Ni.

The first pillar body 131 has a pair of first symmetrical raised blocks 133 extended toward both directions of the first Y-axis 102 and the second pillar body 141 has a pair of second symmetrical raised blocks 143 extended toward both directions of the second Y-axis 103. The first symmetrical raised blocks 133 and the second symmetrical raised blocks 143 are disposed on the passivation layer 120, i.e., the disposed positions of the first symmetrical raised blocks 133 and the second symmetrical raised blocks 143 are larger than the corresponding first opening 121 and the corresponding second opening 122. Moreover, the heights of the first symmetrical raised blocks 133 and the second symmetrical raised blocks 143 are slightly higher than the central heights of the first pillar body 131 and the second pillar body 141 to enhance the solder joint support to symmetrical micro bumps of flip chip or TSV. The horizontal extended lengths from the first symmetrical raised blocks 133 and from the second symmetrical raised blocks 143 to the adjacent corresponding first opening 121 and to the corresponding second opening 122 can not be less than 7 μm such as 14.5 μm or 20 μm to further enhance the symmetrical support capability of pillar bumps. The first symmetrical raised blocks 133 and the second symmetrical raised blocks 143 physically have the same shapes and dimensions to achieve perfect symmetrical extension of pillar bumps on the passivation layer 120. To be more specific, the top surfaces of the first pillar body 131 and the second pillar body 141 individually have central indentation 134 and 144 to individually accommodate the corresponding first solder cap 132 and the corresponding second solder cap 142 to reduce the solder bleeding after flip-chip bonding.

Furthermore, each of the first pillar body 131 and the second pillar body 141 individually has a shrunk bump width along the X-axis 101 and is around 85% of the opening width such as 36 μm so that the first pillar body 131 and the second pillar body 141 have a second aspect ratio where the second aspect ratio is about 1.5 times greater than the first aspect ratio to partially expose the first bonding pad 111 and the second bonding pad 112 so that the central point 136 of the first pillar body 131 along the first Y-axis 102 is vertically aligned to the central point 125 of the first opening 121 as shown in FIG. 3 and the central point 146 of the second pillar body 141 along the second Y-axis 103 is vertically aligned to the central point 126 of the second opening 122. When the first aspect ratio is 1, then the second aspect ratio will be 1.5 or more. In the present embodiment, when each side of the first symmetrical raised blocks 133 and the second symmetrical raised blocks 143 is about 7 μm, therefore, the length of the first pillar body 131 with the length of the corresponding first symmetrical raised blocks 133 and the length of the second pillar body 141 with the second symmetrical raised blocks 143 will be 56 μm, respectively. When 56 μm of the total length is divided by 36 μm of the bump width, the second aspect ratio is 1.55 to be more specific.

Preferably, the length of each side of the first symmetrical raised blocks 133 and the second symmetrical raised blocks 143 is greater than 10 μm so that the lengths of the first pillar body 131 and the second pillar body 141, 62 μm to be more specific, can not be smaller than the above mentioned distance, 60 μm to be more specific, from the central point 125 of the first opening 121 to the central point 126 of the second opening 122. The above mentioned bump width is not greater than 75% of the distance from the central point 125 of the first opening 121 to the central point 126 of the second opening 122, i.e., the total length of each pillar body including the length of the symmetrical raised blocks will not be less than the pitch of the pillar bumps and the width of each pillar bump will not be greater than 75% of the pitch between pillar bumps to form fine-pitch symmetrical pillar bump layout structures with higher aspect ratios. In the present embodiment, the lengths of the first pillar body 131 and the second pillar body 141 are 62 μm which is not less than the above mentioned bump pitch, 60 μm to be more specific, and the bump widths of the first pillar body 131 and the second pillar body 141 are 36 ₁u m which is about 60% of the above mentioned bump pitch, 60 μm to be more specific, and is not greater than 75%.

Moreover, the fine-pitch pillar bump layout structure 100 further includes a first UBM 151 and a second UBM 152 where the first UBM 151 is disposed between the first pillar body 131 and the first bonding pad 111 without covering the partially exposed area of the first bonding pad 111 and the second UBM 152 is disposed between the second pillar body 141 and the second bonding pad 112 without covering the partially exposed area of the second bonding pad 112 to accommodate the solder bleeding from the top surfaces of the pillar bumps. Furthermore, the first UBM 151 and the second UBM 152 are further individually extended to and disposed under the first symmetrical raised blocks 133 and the second symmetrical raised blocks 143 to form the first symmetrical raised blocks 133 and the second symmetrical raised blocks 143 by plating processes and to improve the adhesion of the first symmetrical raised blocks 133 and the second symmetrical raised blocks 143.

Therefore, the fine-pitch pillar bump layout structure 100 of the present invention is to prevent solder bridging between fine-pitch micro bumps leading to electrical short and to provide enough soldering area of fine-pitch pillar bumps aligned and jointed to the passivation opening of the bonding pads and to achieve the best combination of balanced solder-jointing stresses. Moreover, the gap between micro bumps can increase 5 μm to 6 μm to enhance the complete filling of underfill material.

According to a various embodiment of the present invention, another fine-pitch pillar bump layout structure on chip is also revealed in FIG. 5 for a cross-sectional view which is almost the same as the previous embodiments with similar structures and with the same component names and numbers where the detail description of each component will not be explained again.

The fine-pitch pillar bump layout structure 200 includes a chip 110, a passivation layer 120, a first pillar bump 130, and a second pillar bump as same as the second pillar bump 140 in first embodiment shown in FIGS. 1-4. The first pillar bump 130 is disposed on the first bonding pad 111 and includes a first pillar body 131 and a first solder cap 132. The second pillar bump is disposed on the second bonding pad and includes a second pillar body and a second solder cap. The first pillar body 131 has a pair of first symmetrical raised blocks extended toward both directions of the first Y-axis and the second pillar body has a pair of second symmetrical raised blocks extended toward both directions of the second Y-axis. The first pillar body 131 and the second pillar body 141 individually have a plurality of shrunk bump widths along the X-axis so that the first pillar body 131 and the second pillar body have a second aspect ratio where the second aspect ratio is about 1.5 times greater than the first aspect ratio to partially expose the first bonding pad 111 and the second bonding pad so that the central point of the first pillar body 131 along the first Y-axis is vertically aligned to the central point of the first opening 121 and the central point of the second pillar body along the second Y-axis is vertically aligned to the central point of the second opening.

Furthermore, the fine-pitch pillar bump layout structure 200 further includes a third pillar bump 260 disposed on the passivation layer 120. The third pillar bump 260 includes a third pillar body 261 and a third solder cap 26 where the height of the third pillar bump 260 is about the same as the heights of the first symmetrical raised blocks 133 and the second symmetrical raised blocks 143 with a variation of 2 μm to 3 μm. A third barrier layer 263 is disposed between the third pillar body 261 and the third solder cap 262 where a third UBM 253 is disposed between the third pillar body 261 and the passivation layer 120. The third pillar bump 260 can be an alignment mark, a dummy bump or a physical support to keep chip horizontal during flip-chip bonding so that the first pillar bump 130 and the second pillar bump 140 can be aligned and disposed on the corresponding first bonding pad 111 and the corresponding second bonding pad 112 without RDL (Redistribution layer). Moreover, the third pillar bump 260 is completely disposed on the passivation layer 120 so that the total height of the third pillar bumps 260 has already included the height of the passivation layer 120, therefore, symmetrical raised blocks will not be needed.

Therefore, another fine-pitch pillar bump layout structure on chip can be implemented to improve non-coplanarity issue of pillar bumps with different functions disposed on bonding pads as well as on the composite passivation layer.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

1. A fine-pitch pillar bump layout structure on chip, comprising:
a chip having a first bonding pad and a second bonding pad disposed on an active surface along an X-axis;
a passivation layer disposed on the active surface of the chip and having a first opening and a second opening with a first aspect ratio; wherein the distance from the central point of the first opening to the central point of the second opening is defined on the X-axis and is not greater than 80 μm; wherein a first Y-axis and a second Y-axis is parallel to each other and perpendicular to the X-axis where the central point of the first opening is located on the first Y-axis and the central point of the second opening is located on the second Y-axis;
a first pillar bump disposed on the first bonding pad and including a first pillar body and
a first solder cap; and
a second pillar bump disposed on the second bonding pad and including a second pillar body and a second solder cap;
whereas the first pillar body has a pair of first symmetrical raised blocks extended toward both directions of the first Y-axis and the second pillar body has a pair of second symmetrical raised blocks extended toward both directions of the second Y-axis wherein the first symmetrical raised blocks and the second symmetrical raised blocks are disposed on the passivation layer and the first pillar body and the second pillar body individually have shrunk bump widths along the X-axis so that the first pillar body and the second pillar body have a second aspect ratio which is at least 1.5 times greater than the first aspect ratio to partially and symmetrically expose the first bonding pad and the second bonding pad between the first pillar bump and the second pillar bump, wherein the cross-sectional line of the first pillar body along the first Y-axis is vertically aligned to the central point of the first opening, wherein the cross-sectional line of the second pillar body is aligned to the central point of the second opening, wherein the extending directions of the first and second symmetrical raised blocks are perpendicular to the disposition direction of the first and second pillar bumps.

2. The layout structure as claimed in claim 1, wherein the top surfaces of the first pillar body and the second pillar body individually have central indentation comparing to the first and second symmetrical raised blocks to individually accommodate the first solder cap and the second solder cap.

3. The layout structure as claimed in claim 2, further comprising a first UBM and a second UBM wherein the first UBM is disposed between the first pillar body and the first bonding pad without covering the partially exposed area of the first bonding pad, and the second UBM is disposed between the second pillar body and the second bonding pad without covering the partially exposed area of the second bonding pad.

4. The layout structure as claimed in claim 3, wherein the first UBM and the second UBM are individually extended to and disposed under the corresponding first symmetrical raised blocks and the corresponding second symmetrical raised blocks

5. The layout structure as claimed in claim 1, wherein a first barrier layer is disposed between the first pillar body and the first solder cap and a second barrier layer is disposed between the second pillar body and the second solder cap.

6. The layout structure as claimed in claim 1, wherein the passivation layer includes a primary passivation and an additional organic passivation.

7. The layout structure as claimed in claim 1, wherein the horizontal distance between each of the first symmetrical raised blocks to the adjacent corresponding first opening and the horizontal distance of each of the second symmetrical raised blocks to the adjacent corresponding second opening are not less than 7 μm.

8. The layout structure as claimed in claim 1, wherein the first pillar bump along the first Y-axis and the second pillar bump the second Y-axis have a bump length not less than the above mentioned distance between the central point of the first opening and the central point of the second opening through the disposition of the first symmetrical raised blocks and the second symmetrical raised blocks, wherein the first pillar bump and the second pillar bump the X-axis have a bump width not greater than 75% of the distance from the central point of the first opening to the central point of the second opening.

9. The layout structure as claimed in claim 1, wherein the first symmetrical raised blocks and the second symmetrical raised blocks physically have the same shapes and dimensions.

10. The layout structure as claimed in claim 1, further comprising a third pillar bump completely disposed on the passivation layer and including a third pillar body and a third solder cap where the height of the third pillar body is about the same as the first symmetrical raised blocks.
